(19) United States
(12) Patent Application Publication
(10) Pub. No.: US 2008/0090334 A1
(43) Pub. Date: Apr. 17, 2008

(54) Method for Manufacturing Semiconductor Device

(76) Inventor: Kuan-Chun Chen, Taichung Hsien (TW)

Correspondence Address: THOMAS, KAYDEN, HORSTEMEYER & RISLEY, LLP, 600 GALLERIA PARKWAY, S.E., STE 1500, ATLANTA, GA, 30339-5994, US

(21) Appl. No.: 11/840,342

(22) Filed: Aug. 17, 2007

(30) Foreign Application Priority Data
Oct. 12, 2006 (TW) 95137588

(51) Int. Cl. H01L 21/00

(52) U.S. Cl. 438/118; 257/E23.08

(57) ABSTRACT

A method for manufacturing a semiconductor device is described. The method comprises: providing a mold; coating a glue on a surface of the mold; providing at least one semiconductor chip, wherein the semiconductor chip includes a first side and a second side on opposite sides, and the first side of the semiconductor chip is pressed into a portion of the glue to expose the second side of the semiconductor chip; forming an adhesive layer to cover the second side of the semiconductor chip and the exposed portion of the glue; forming a metal heat sink on the adhesive layer; removing the glue and the mold; disposing a circuit board on the exposed portion of the adhesive layer; providing wires to electrically connect the circuit board to the semiconductor chip; and forming an encapsulation layer to completely encapsulate the semiconductor chip, the wires and the exposed portion of the adhesive layer.

### RELATED APPLICATIONS

This application claims priority to Taiwan Application Serial Number 95137588, filed Oct. 12, 2006, which is herein incorporated by reference.

### FIELD OF THE INVENTION

The present invention relates to a method for manufacturing a semiconductor device, and more particularly, to a method for manufacturing a metal heat sink for a semiconductor device.

### BACKGROUND OF THE INVENTION

Currently, packaging techniques for semiconductor devices, such as transistors, integrated circuits, or opto-electrical devices including light-emitting diodes (LEDs), laser diodes (LDs) and solar cells, are performed by using glue or solder paste to connect chips and frames or sub-mounts while flip-chip techniques are performed by using metal bumps to connect chips and substrates.

When semiconductor chips are applied in a large or small backlight module or illumination module, many semiconductor chips are needed to generate sufficient brightness or illumination for the modules. However, when the semiconductor chips are operated at high power, the temperature of the module composed of the semiconductor elements or opto-electrical devices increases rapidly, thereby degrading the operational quality and decreasing the life of the module and ultimately burning out the opto-electrical devices.

To resolve this high temperature issue, modules composed of semiconductor devices are typically cooled by fans set in the module or by increasing the heat dissipation area. However, regarding setting fans in the module, the vibration caused by the operation of the fans results in the lights flickering, and the fans consume additional power. In addition, setting fans and increasing heat dissipation area both greatly increase the volume of the system. Regarding increasing the heat dissipation area, although the heat sinks can be composed of metal with high thermal conductivity, glue mixed with metal is used to connect the opto-electrical device and the heat sinks, and the thermal conductivity of the glue is much lower than that of the pure metal. As a result, the heat generated during the operation of the opto-electrical device mostly accumulates at the connection interface, so that the heat sinks cannot transfer heat well, thereby making the heat sinks less effective, and easily damaging the opto-electrical devices during long-term operation or ultimately making the opto-electrical devices not being operated with larger input power usage.

In addition, in the process of fixing the semiconductor chips with glue and solder paste or in the flip-chip package processes, the process temperature has to be increased to above 150° C. At this temperature the device properties are easily damaged.

Therefore, with an increasing demand for semiconductor devices for various modules, a simple and easy technique for manufacturing a semiconductor device with high heat-sinking efficiency is required.

### SUMMARY OF THE INVENTION

One aspect of the present invention is to provide a method for manufacturing a semiconductor device, in which glue is coated on a mold or at least one semiconductor chip, so that the semiconductor chip can be fixed on the mold. As a result, the uneven adhesion between the adhesive tape and the mold is solved, and air bubbles being formed between the adhesive tape and the mold is prevented, thereby effectively reducing difficulty in the disposition process of the metal heat sink and enhancing the process yield.

Another aspect of the present invention is to provide a method for manufacturing a semiconductor device, in which glue is directly coated on at least one semiconductor chip or a mold, so that the semiconductor chip can be fixed to the mold successfully. As a result, a heat-sinking metal can be directly deposited on a bottom surface of the semiconductor chip, and the semiconductor chip can be set on the metal heat sink without glue or solder paste. Therefore, the temperature of the operating device can be rapidly and effectively lowered to improve the operational quality of the device and prolong the life of the device.

Still another aspect of the present invention is to provide a method for manufacturing a semiconductor device, in which a heat-sinking metal can be directly deposited on a bottom surface of the semiconductor chip by adhering at least one semiconductor chip onto a mold with glue. The glue can be coated onto the mold in any shape smoothly and without any air bubbles, so that a heat sink in any shape may be produced to satisfy the needs of various products. Furthermore, the cost of the glue is much lower than that of the adhesive tape, so that the process cost is lowered.

Another aspect of the present invention is to provide a method for manufacturing a semiconductor device, which can mount a semiconductor chip onto a metal heat sink at very low temperature, so that it can prevent the optical and electrical properties of the device from being damaged.

According to the aforementioned aspects, the present invention provides a method for manufacturing a semiconductor device, comprising: providing a mold; coating a glue on a surface of the mold; providing at least one semiconductor chip, wherein the semiconductor chip includes a first side and a second side on opposite sides, and the first side of the semiconductor chip is pressed into a portion of the glue to expose the second side of the semiconductor chip; forming an adhesive layer to cover the second side of the semiconductor chip and the exposed portion of the glue; forming a metal heat sink on the adhesive layer; removing the glue and the mold; disposing a circuit board on the exposed portion of the adhesive layer; providing a plurality of wires to electrically connect the circuit board to the semiconductor chip; and forming an encapsulation layer to completely encapsulate the semiconductor chip, the wires and the exposed portion of the adhesive layer.

According to a preferred embodiment of the present invention, the material of the glue may be a polymer material, a silica material, an epoxy material, a phenolic material, an acrylic material or a photoresist material.

According to the aforementioned aspects, the present invention further provides a method for manufacturing a semiconductor device, comprising: providing at least one semiconductor chip including a first side and a second side on opposite sides; coating a glue on the first side of the semiconductor chip; providing a mold and adhering the first side of the semiconductor chip onto a surface of the mold to expose the second side of the semiconductor chip; forming an adhesive layer to cover the second side of the semiconductor chip, the exposed portion of the glue and the exposed portion of the surface of the mold; forming a metal heat sink on the adhesive layer; and removing the glue and the mold.

According to a preferred embodiment of the present invention, the step of adhering the first side of the semiconductor chip further comprises: providing at least one circuit board, wherein the circuit board is an integrated circuit board comprising at least one insulating layer and at least one electric conduction layer stacked with one another; and coating the glue on the circuit board to make the glue completely cover the electric conduction layer and expose the insulating layer.

### BRIEF DESCRIPTION OF THE DRAWINGS

The foregoing aspects and many of the attendant advantages of this invention are more readily appreciated as the same become better understood by reference to the following detailed description, when taken in conjunction with the accompanying drawings, wherein:

FIGS. 1A through 9B are schematic flow diagrams showing the process for manufacturing a semiconductor device in accordance with a preferred embodiment of the present invention, wherein the schematic flow diagrams includes cross-sectional views and the corresponding top views.

### DETAILED DESCRIPTION OF THE PREFERRED EMBODIMENT

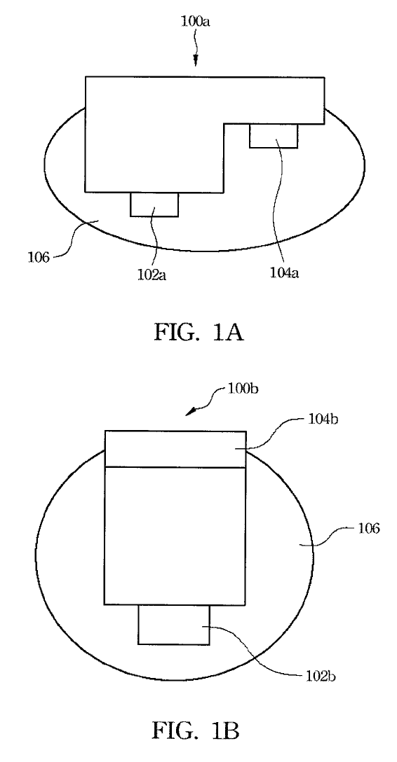

The present invention discloses a method for manufacturing a semiconductor device, in which a heat-sinking metal can be directly deposited on a bottom surface of a semiconductor chip with glue. The connection of the bottom surface of the semiconductor chip and the metal heat sink can be achieved without glue or solder paste, so that the heat sinking efficiency of the semiconductor device can be greatly enhanced. In order to make the illustration of the present invention more explicit, the following description is stated with reference to FIGS. 1A through 9B.

FIGS. 1A through 9B are schematic flow diagrams showing the process for manufacturing a semiconductor device in accordance with a preferred embodiment of the present invention, wherein the schematic flow diagrams includes cross-sectional views and the corresponding top views. Initially, one or more semiconductor chips are provided, wherein the semiconductor chips may be transistors, monolithic integrated circuits (ICs), or opto-electrical chips, such as central processing units (CPUs), light-emitting diode chips, laser diode chips or solar cells. In a preferred embodiment of the present invention, each semiconductor chip includes two electrodes of different conductivity types, wherein the electrodes may be disposed on the same side or on different sides of the semiconductor chip, such as opto-electrical chips 100a shown in FIG. 1A and opto-electrical chips 100b shown in FIG. 1B. In FIG. 1A two opto-electrical chip 100a electrodes 102a and 104a of different conductivity types are disposed on the same side of the opto-electrical chip 100a; and in FIG. 1B two opto-electrical chip 100b electrodes 102b and 104b are disposed on two opposite sides of the opto-electrical chip 100b. While the electrodes 102a/102b are N-type, the electrodes 104a/104b are P-type; and while the electrodes 102a/102b are P-type, the electrodes 104a/104b are N-type. Then, glue 106 is coated on one side of the semiconductor chip 100a/100b including at least one electrode formed thereon, such as shown in FIG. 1A and FIG. 1B. In an exemplary embodiment of the present invention, the glue 106 is adhesive, and the material of the glue 106 is a polymer material, a silica material, an epoxy material, a phenolic material, an acrylic material or a photoresist material for example. The glue 106 is not a solid-state substance, so when the glue 106 is coated onto the semiconductor chip 100a/100b, air bubbles are prevented from forming in the interface b between the semiconductor chip 100a/100b and the glue 106.

In one embodiment, the semiconductor chip is a transistor or a monolithic integrated circuit, and the semiconductor chip may be composed of a silicon-based material or a compound semiconductor material, wherein the compound semiconductor material is a GaN-based material, an AlGaInP-based material, a PbS-based material or a SiC-based material for example. In another embodiment, the semiconductor chip is an opto-electrical chip, and the opto-electrical chip may be composed of a silicon-based material or a compound semiconductor material, wherein the compound semiconductor material is a GaN-based material, an AlGaInP-based material, a PbS-based material or a SiC-based material for example.

In the following exemplary embodiment, three opto-electrical chips 100b are adopted as the semiconductor chips to illustrate a process of the present invention.

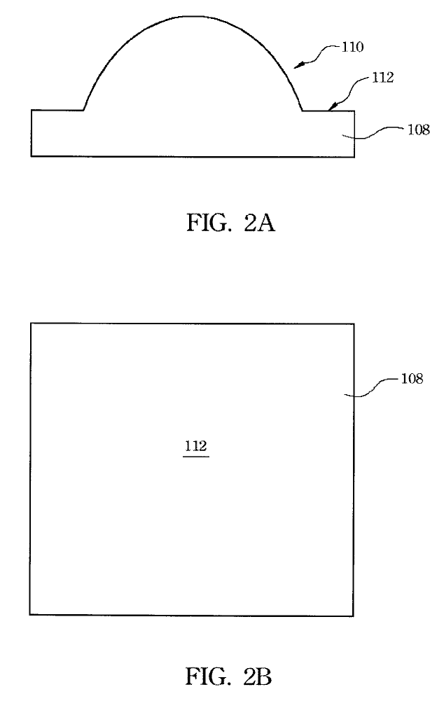

A mold 108 is provided, such as shown in FIG. 2A and FIG. 2B, wherein FIG. 2A is the cross-sectional view and FIG. 2B is the corresponding top view. In the present invention, the mold may include a plane surface and the mold is a plane substrate for example, or a shape of the mold may be designed according to the product needs, so that a surface of the mold includes a three-dimensional structure for example. In the exemplary embodiment, according to the product needs, a surface 112 of the mold 108 includes a three-dimensional structure 110, such as shown in FIG. 2A.

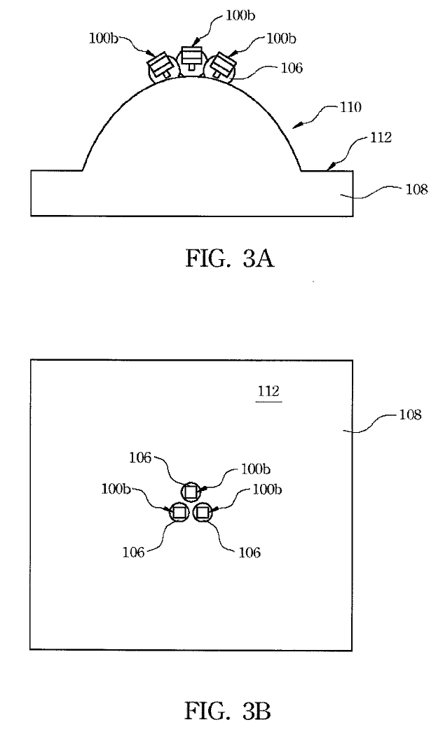

Then, the side of each opto-electrical chip 100b coated with the glue 106 is adhered to the three-dimensional structure 110 of the surface 112 of the mold 108 to make the opposite side of the opto-electrical chip 100b face upward and be exposed, such as shown in FIG. 3A and FIG. 3B, wherein FIG. 3A is the cross-sectional view and FIG. 3B is the corresponding top view.

In another embodiment of the present invention, the glue 106 may be first coated on the surface 112 of the mold 108, and then one side of each opto-electrical chip 100b including at least one electrode formed thereon is pressed into a portion of the glue 106 to make the opposite side of the opto-electrical chip 100b be exposed. The glue 106 is not a solid-state substance, so that the glue 106 can be coated on the surface 112 of the mold in any shape smoothly and without any air bubble, and the process is much easier than the process using adhesive tape.

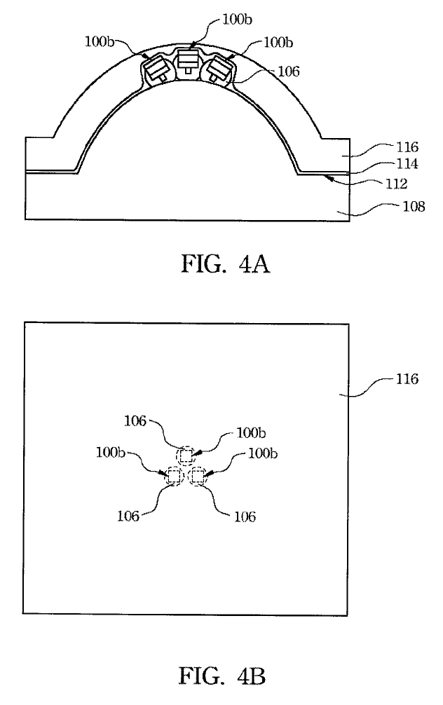

After the opto-electrical chips 100b are adhered to the surface 112 of the mold 108, an adhesive layer 114 is directly formed to cover the exposed surface of the opto-electrical chips 100b, the exposed portion of the glue 106 and the exposed region of the surface 112 of the mold 108 by, for example, an evaporation deposition method, a sputtering deposition method or an electroless plating deposition method. The adhesive layer 114 is preferably composed of a metal material with good adhesive properties. In the exemplary embodiment, the material of the adhesive layer 114 is Zn, ZnO, ITO, TaN, TiN, Ni, Cr, Ti, Ta, Al, AlN, AlₓO_{y}, GaN, InGaN, SiₓN_{y}, In, InN, Au, Ag, Cu, Zn, Pt, Pd, Ru, Rh, carbon nano-tube/Au, C/Au, diamond, diamond/Au, diamond/Ni/Au, Ni alloy, Cr alloy, Ag alloy, Au alloy, Cu alloy, Ti alloy, Ta alloy, Al alloy or In alloy. A thickness of the adhesive layer 114 is preferably less than about 10 μm. Then, a heat sink of the semiconductor chips may be directly formed, or a reflective layer is selectively formed on the semiconductor chips according to the product needs. For example, as shown in FIGS. 4A and 4B, in which FIG. 4A is the cross-sectional view and FIG. 4B is the corresponding top view, a metal reflective layer 116 is formed to cover the adhesive layer 114 on the opto-electrical chips 100b by, for example, an evaporation deposition method, a sputtering deposition method, an electroless plating deposition method or an electro plating deposition method. The metal reflective layer 116 may be composed of a metal material of high reflectivity, such as Al, Ag, Au, Cu, Rh, Pt, Cr, Ni, Ti, or any alloy of the aforementioned metal. The metal reflective layer 116 may be composed of a single-layer metal structure or a multi-layered metal structure. In the exemplary embodiment, a thickness of the metal reflective layer 116 is preferably less than about 10 μm.

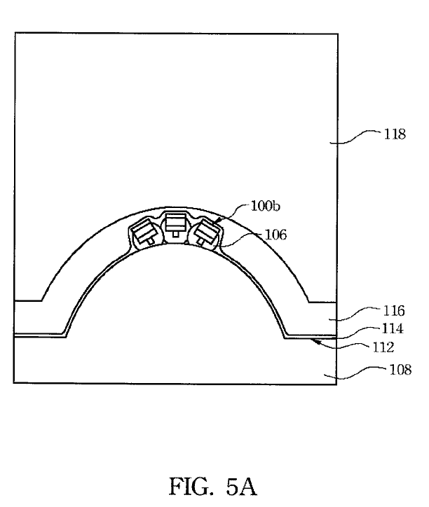

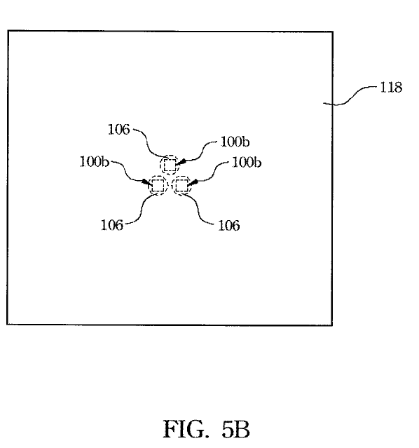

Next, a metal heat sink 118 composed of a thicker metal layer is formed to cover the metal reflective layer 116 by, for example, an electro plating deposition method or an electroless plating deposition method, such as shown in FIG. 5A and FIG. 5B, in which FIG. 5A is the cross-sectional view and FIG. 5B is the corresponding top view. In the exemplary embodiment, the metal heat sink 118 is formed on the base of the metal reflective layer 116. In the other embodiment, the metal heat sink 118 is formed on the base of the adhesive layer 114 while no metal reflective layer is formed. Because the metal heat sink 118 is formed by an electro plating deposition method or an electroless plating deposition method in the exemplary embodiment, the metal heat sink 118 is only grown on the metal reflective layer 116 substantially. In the exemplary embodiment, the metal heat sink 118 is preferably composed of a metal of good thermal conductivity, such as Cu, Au/Cu, Ag/Cu, Ag/Au/Cu, Cu alloy, Fe/Ni alloy, Ni, Ni/Cu, Ni/Au/Cu, Ni/Ag/Au/Cu, W, CuW, or any alloy of the aforementioned metal. The metal heat sink 16 is generally thicker and preferably has a thickness greater than about 10 μm for larger heat conduction and larger thermal capacity.

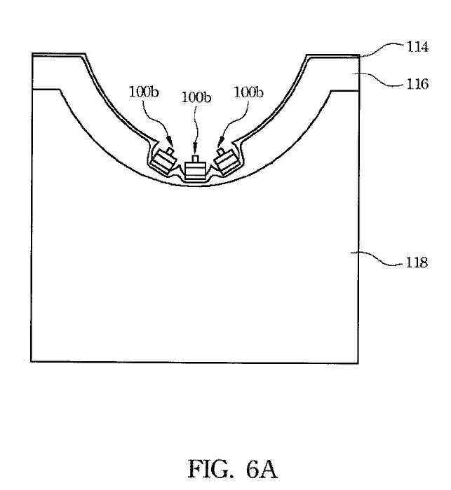

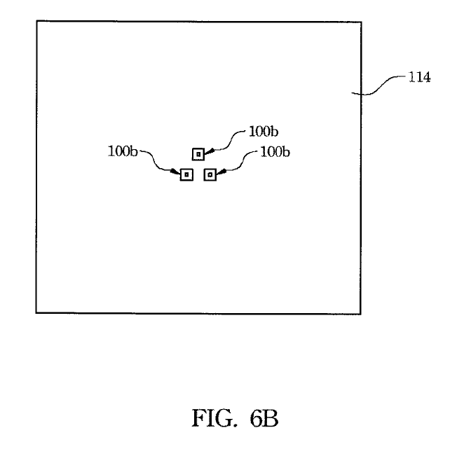

After the formation of the metal heat sink 118 is completed, the glue 106 and the mold 108 are removed to expose the portion of the opto-electrical chips 100b originally covered by the glue 106, and to expose the adhesive layer simultaneously, such as shown in FIG. 6A and FIG. 6B, in which FIG. 6A is the cross-sectional view and FIG. 6B is the corresponding top view. Subsequently, a dicing step is selectively performed according to the product needs so as to form the metal heat sink 118 with an appropriate size.

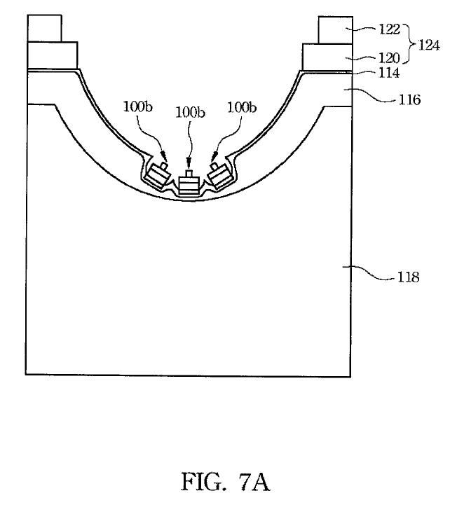

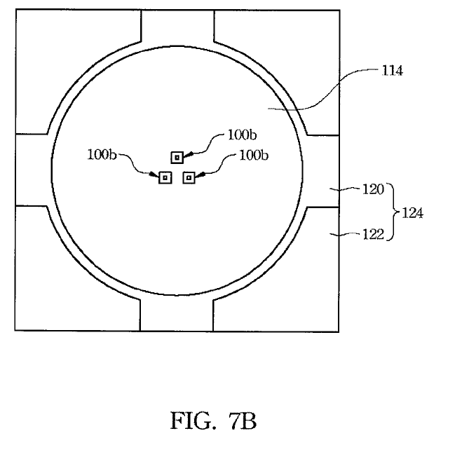

Next, one or more circuit boards 124 are set according to the product needs, such as shown in FIG. 7A and FIG. 7B, in which FIG. 7A is the cross-sectional view and FIG. 7B is the corresponding top view. Each circuit board 124 may be an integrated circuit board comprising at least one insulating layer 120 and at least one electric conduction layer 122 stacked on the adhesive layer 114 in sequence. The insulating layer 120 is interposed between the adhesive layer 114 and the electric conduction layer 122 to electrically isolate the adhesive layer 114 and the electric conduction layer 122. According to the variation of the shape of the mold 108, the electric conduction layer 122 may be in any pattern, such as shown in FIG. 7B.

Although in the aforementioned embodiment, the circuit board 124 is set after the mold 108 and the glue 106 are removed, the present invention is not limited thereto. In the other embodiment, when one side of each semiconductor chip 100b is coated with the glue 106, the circuit board 124 is simultaneously coated with the glue 106, wherein the glue 106 entirely covers the electric conduction layer 122 of the circuit board 124 to prevent the conductive adhesive layer 114 formed subsequently from being in contact and electrically connection with the electric conduction layer 122. The insulating layer 120 is not completely covered with the glue 106 and is exposed. Then, similar to the semiconductor chips 100b, the circuit board 124 is adhered to the surface 112 of the mold 108 by the glue, so that the adhesive layer 114 subsequently deposited on the surface 112 of the mold 108 simultaneously covers the exposed portion of the insulating layer 120 of the circuit board 124. Then, the following processes are performed as described in the aforementioned exemplary embodiment.

In still another embodiment of the present embodiment, the glue 106 is first coated on the surface 112 of the mold 108, and when the opto-electrical chips 100b are pressed into a portion of the glue 106, the circuit board 124 may be pressed into another portion of the glue 106 simultaneously. When the circuit board 124 is pressed into the glue 106, the electric conduction layer 122 is completely encapsulated in the glue 106, and the insulating layer 120 is exposed, so as to prevent the conductive adhesive layer 114 formed sequentially from being in contact and electrically connection with the electric conduction layer 122. As a result, the adhesive layer 114 subsequently deposited on the surface 112 of the mold 108 can simultaneously cover the exposed portion of the insulating layer 120 of the circuit board 124. Then, following processes are performed as described in the aforementioned exemplary embodiment.

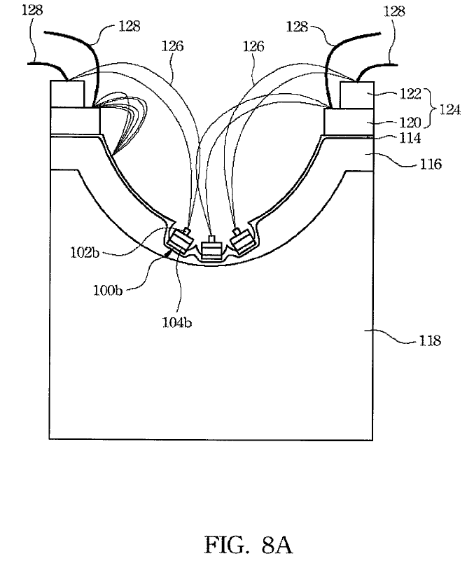

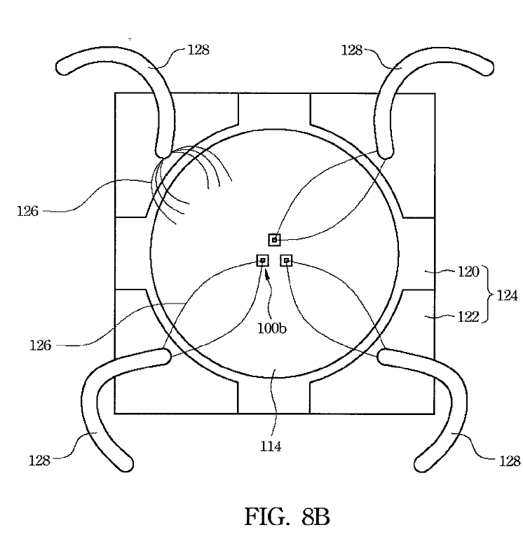

After the circuit board 124 is set, a plurality of wires 126 are set to electrically connect the electrodes 102b and 104b of different conductivity types to pads (not shown) of corresponding conductivity types on the electric conduction layer 122 of the circuit board 124 respectively. Then, a plurality of external wires 128 are set to respectively connect the pads of the same conductivity type on the electric conduction layer 122 of the circuit board 124, such as shown in FIG. 8A and FIG. 8B, in which FIG. 8A is the cross-sectional view and FIG. 8B is the corresponding top view. Accordingly, the opto-electrical chips 100 b are electrically connected to an external circuit successfully through the wires 126 and the external wires 128.

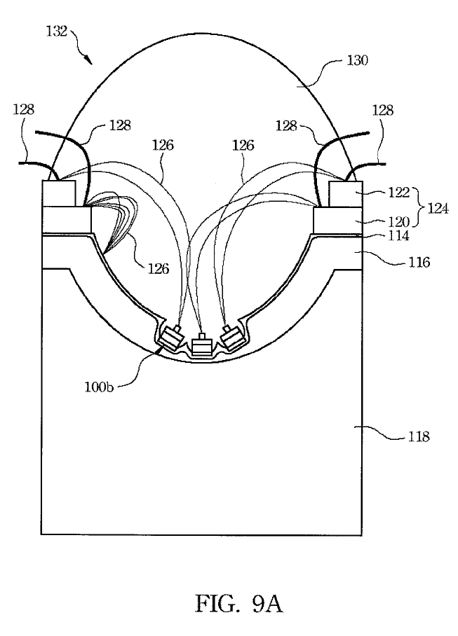

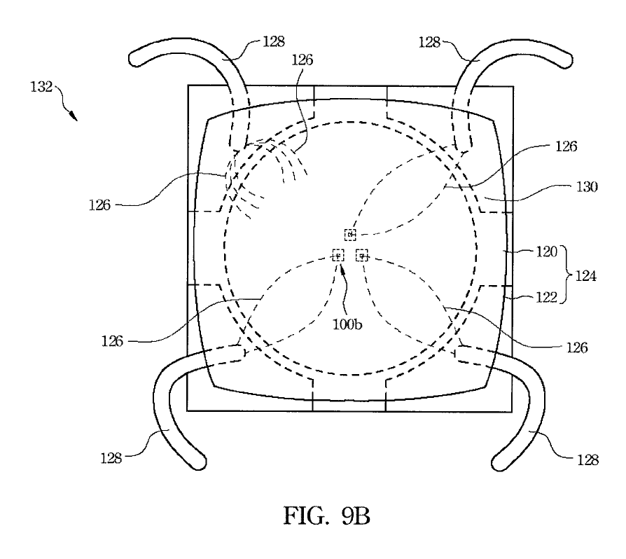

Then, an encapsulation procedure may be performed to form an encapsulation layer 130 to completely encapsulate the opto-electrical chips 100b, all of the wires 126, the exposed portion of the adhesive layer 114, the connection regions of the external wires 128 and the wires 126, and a portion of the circuit board 124, so as to complete the fabrication of a semiconductor device 132, such as shown in FIG. 9A and FIG. 9B, in which FIG. 9A is the cross-sectional view and FIG. 9B is the corresponding top view.

According to the aforementioned description, one advantage of the present invention is that a method for manufacturing a semiconductor device of an exemplary embodiment coats a mold or at least one semiconductor chip with glue, so that the semiconductor chip can be fixed on the mold. Accordingly, the uneven adhesion between the adhesive tape and the mold is overcome, and any air bubble is prevented from being formed between the adhesive tape and the mold, thereby effectively reducing difficulty in the disposition process of the metal heat sink and enhancing the process yield.

According to the aforementioned description, another advantage of the present invention is that in a method for manufacturing a semiconductor device of an exemplary embodiment, glue is directly coated on at least one semiconductor chip or a mold, so that the semiconductor chip can be fixed to the mold successfully. As a result, a heat-sinking metal can be directly deposited on a bottom surface of the semiconductor chip, and the semiconductor chip can be set on the metal heat sink without glue or solder paste. Therefore, the temperature of the operating device can be rapidly and effectively lowered to improve the operational quality of the device and prolong the life of the device.

According to the aforementioned description, still another advantage of the present invention is that in a method for manufacturing a semiconductor device of an exemplary embodiment, a heat-sinking metal can be directly deposited on a bottom surface of the semiconductor chip by adhering at least one semiconductor chip onto a mold with glue. The glue can be coated onto the mold in any shape smoothly and without air bubbles, so that a heat sink in any shape may be produced to satisfy needs of various products. Furthermore, the cost of the glue is much lower than that of the adhesive tape, so that the process cost is lowered.

According to the aforementioned description, another advantage of the present invention is that a method for manufacturing a semiconductor device of an exemplary embodiment coats glue onto a mold in any shape or at least one semiconductor chip uniformly, and a metal reflective layer and a metal heat sink in any shape are formed in one piece after an evaporation process, an electro plating process or an electroless plating process is performed. Accordingly, function and the applied value of products are greatly increased.

According to the aforementioned description, still further another advantage of the present invention is that a method for manufacturing a semiconductor device of an exemplary embodiment can mount a semiconductor chip onto a metal heat sink at very low temperature, such as lower than 30° C., so that it can prevent the optical and electrical properties of the device from being damaged.

As is understood by a person skilled in the art, the foregoing preferred embodiments of the present invention are illustrated of the present invention rather than limiting of the present invention. It is intended to cover various modifications and similar arrangements included within the spirit and scope of the appended claims, the scope of which should be accorded the broadest interpretation so as to encompass all such modifications and similar structure.

What is claimed is:

1. A method for manufacturing a semiconductor device, comprising:
providing a mold;
coating a glue on a surface of the mold;
providing at least one semiconductor chip including a first side and a second side on opposite sides, and the first side of the semiconductor chip is pressed into a portion of the glue to expose the second side of the semiconductor chip;
forming an adhesive layer to cover the second side of the semiconductor chip and the exposed portion of the glue;
forming a metal heat sink on the adhesive layer; and
removing the glue and the mold.

2. The method for manufacturing a semiconductor device according to claim 1, wherein the surface of the mold includes a three-dimensional structure or the surface of the mold is a plane surface.

3. The method for manufacturing a semiconductor device according to claim 1, wherein a material of the glue is a polymer material, a silica material, an epoxy material, a phenolic material, an acrylic material or a photoresist material.

4. The method for manufacturing a semiconductor device according to claim 1, wherein a material of the adhesive layer is Zn, ZnO, ITO, TaN, TiN, Ni, Cr, Ti, Ta, Al, AlN, AlₓO_{y}, GaN, InGaN, SiₓN_{y}, In, InN, Au, Ag, Cu, Zn, Pt, Pd, Ru, Rh, carbon nano-tube/Au, C/Au, diamond, diamond/Au, diamond/Ni/Au, Ni alloy, Cr alloy, Ag alloy, Au alloy, Cu alloy, Ti alloy, Ta alloy, Al alloy or In alloy.

5. The method for manufacturing a semiconductor device according to claim 1, wherein a thickness of the adhesive layer is less than about 10 μm.

6. The method for manufacturing a semiconductor device according to claim 1, wherein the step of forming the adhesive layer is performed by an evaporation deposition method, a sputtering deposition method or an electroless plating deposition method.

7. The method for manufacturing a semiconductor device according to claim 1, wherein a material of the metal heat sink is Cu, Au/Cu, Ag/Cu, Ag/Au/Cu, Cu alloy, Fe/Ni alloy, Ni, Ni/Cu, Ni/Au/Cu, Ni/Ag/Au/Cu, W, CuW, or an alloy thereof.

8. The method for manufacturing a semiconductor device according to claim 1, wherein a thickness of the metal heat sink is greater than about 10 μm.

9. The method for manufacturing a semiconductor device according to claim 1, wherein the step of forming the metal heat sink is performed by an electro plating deposition method or an electroless plating deposition method.

10. The method for manufacturing a semiconductor device according to claim 1, further comprising forming a metal reflective layer to cover the adhesive layer between the step of forming the adhesive layer and the step of forming the metal heat sink.

11. The method for manufacturing a semiconductor device according to claim 10, wherein a thickness of the metal reflective layer is less than about 10 μm.

12. The method for manufacturing a semiconductor device according to claim 10, wherein the step of forming the metal reflective layer is performed by an evaporation deposition method, a sputtering deposition method, an electroless plating deposition method or an electro plating deposition method.

13. The method for manufacturing a semiconductor device according to claim 10, wherein a material of the metal reflective layer is Zn, Al, Ag, Au, Cu, Ru, Rh, Pt, Pd, Cr, Ni, Ti, or an alloy thereof.

14. The method for manufacturing a semiconductor device according to claim 1, wherein the step of pressing the semiconductor chip further comprises:
providing at least one circuit board, wherein the circuit board is an integrated circuit board comprising at least one insulating layer and at least one electric conduction layer stacked with one another; and
pressing the electric conduction layer of the circuit board into another portion of the glue completely while exposing the insulating layer, wherein the adhesive layer covers the exposed portion of the insulating layer of the circuit board.

15. The method for manufacturing a semiconductor device according to claim 14, further comprising forming a plurality of wires to electrically connect the electric conduction layer and the semiconductor chip after the step of removing the glue and the mold.

16. The method for manufacturing a semiconductor device according to claim 15, further comprising forming an encapsulation layer to completely encapsulate the semiconductor chip, the wires, an exposed portion of the adhesive layer and connection regions of the wires and the electric conduction layer after the step of forming the wires.

17. The method for manufacturing a semiconductor device according to claim 1, further comprising disposing at least one circuit board on an exposed portion of the adhesive layer after the step of removing the glue and the mold, wherein the circuit board is an integrated circuit board comprising at least one insulating layer and at least one electric conduction layer stacked on the adhesive layer in sequence.

18. The method for manufacturing a semiconductor device according to claim 17, further comprising forming a plurality of wires to electrically connect the electric conduction layer and the semiconductor chip after the step of disposing the circuit board.

19. The method for manufacturing a semiconductor device according to claim 18, further comprising forming an encapsulation layer to completely encapsulate the semiconductor chip, the wires, the exposed portion of the adhesive layer and connection regions of the wires and the electric conduction layer after the step of forming the wires.

20. A method for manufacturing a semiconductor device, comprising:
providing at least one semiconductor chip including a first side and a second side on opposite sides;
coating a glue on the first side of the semiconductor chip;
providing a mold and adhering the first side of the semiconductor chip onto a surface of the mold to expose the second side of the semiconductor chip;
forming an adhesive layer to cover the second side of the semiconductor chip, the exposed portion of the glue and the exposed portion of the surface of the mold;
forming a metal heat sink on the adhesive layer; and
removing the glue and the mold.
